(19) United States
(12) Patent Application Publication
(10) Pub. No.: US 2013/0250494 A1
(43) Pub. Date: Sep. 26, 2013

(54) ELECTRONIC DEVICE SUPPORTER

(71) Applicants: PO-SHENG WANG, NEW TAIPEI CITY (TW); CHING-FENG HSIEH, TAIPEI CITY (TW)

(72) Inventors: PO-SHENG WANG, NEW TAIPEI CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/494,109

(22) Filed: Jun. 12, 2012

(30) Foreign Application Priority Data
Mar. 23, 2012 (TW) 101110128

(51) Int. Cl. H05K 7/00

(52) U.S. Cl. 361/679.01

(57) ABSTRACT

An electronic device supporter fixes the electronic device to a rear-view mirror base inside a vehicle and includes an adjustive support portion, a coupling portion, and an engaging portion. The adjustive support portion adjusts the position of the electronic device relative to the rear-view mirror base. The coupling portion is disposed beside the adjustive support portion and coupled to the electronic device. The engaging portion is disposed beside the adjustive support portion and engaged with the rear-view mirror base. With the electronic device supporter, not only can the electronic device be firmly installed on a rear-view mirror base inside a vehicle, but the angle of elevation, angle of depression, and position of the electronic device can be adjusted.

### CROSS-REFERENCE TO RELATED APPLICATION

This non-provisional application claims priority under 35 U.S.C. §119(a) on Patent Application No(s). 101110128 filed in Taiwan, R.O.C. on Mar. 23, 2012, the entire contents of which are hereby incorporated by reference.

### FIELD OF TECHNOLOGY

The present invention relates to electronic device supporters, and more particularly, to an electronic device supporter for fixing an electronic device to the inside of a vehicle.

### BACKGROUND

There is increasingly wide application of various vehicle-oriented electronic devices, such as satellite navigation devices, tachographs, TV sets for use in vehicles, and Electronic Toll Collection (ETC). According to the prior art, the vehicle-oriented electronic device is installed on a vehicle by being attached to a windshield of the vehicle by means of a suction cup or by being affixed to a dashboard of the vehicle by means of a backing adhesive.

The aforesaid conventional ways of installing the vehicle-oriented electronic devices on vehicles have serious drawbacks. For instance, with windshields being variable in terms of curvature and susceptible to sunshine-induced deformation, suction between the suction cup and the windshield is likely to happen to be insufficient to prevent detachment of the suction cup from the windshield in certain situations, such as strong vibration. If the detachment of the suction cup happens during a drive, the vehicle-oriented electronic devices will fall off the windshield and cause a danger to the vehicle. For instance, if the vehicle-oriented electronic device is affixed to a dashboard with a backing adhesive, changing the vehicle-oriented electronic device or altering the position of the vehicle-oriented electronic device on the dashboard will require removing the backing adhesive from the dashboard, but the removal process of the backing adhesive is both laborious and detrimental to the esthetic appearance of the dashboard

Accordingly, the present invention provides an electronic device supporter for fixing a vehicle-oriented electronic device to a rear-view mirror base inside a vehicle and adjusting its position, and angle of elevation or angle of depression whichever applicable.

### SUMMARY

It is an objective of the present invention to provide an electronic device supporter for fixing a vehicle-oriented electronic device to a rear-view mirror base inside a vehicle and adjusting the angle of elevation, angle of depression, and position of the vehicle-oriented electronic device.

In order to achieve the above and other objectives, the present invention provides an electronic device supporter for fixing an electronic device to a rear-view mirror base inside a vehicle. The electronic device supporter comprises: an adjustive support portion for adjusting a position of the electronic device relative to the rear-view mirror base; a coupling portion disposed at an end of the adjustive support portion and coupled to the electronic device; and an engaging portion disposed at another end of the adjustive support portion and engaged with and penetrated by the rear-view mirror base.

In an embodiment, the engaging portion comprises a holding element and an adjusting element. The holding element holds the rear-view mirror base, whereas the adjusting element adjusts and fastens the holding element in place, thereby allowing the engaging portion to be fixed to the rear-view mirror base.

In an embodiment, the holding element is a ring-like structure, and the adjusting element comprises a screw nut and a screw penetrating the holding element and fixed in place by the screw nut.

In an embodiment, the engaging portion further comprises a resilience element disposed between the engaging portion and the rear-view mirror base.

In an embodiment, the coupling portion comprises an adjustment element for adjusting positions of the adjustive support portion and the coupling portion and fastening the adjustive support portion and the coupling portion in place.

In an embodiment, the coupling portion has a removable connector for connection with the electronic device.

In an embodiment, the coupling portion is integrally formed with the electronic device.

In an embodiment, the adjustive support portion comprises two rods each having an end connected to the coupling portion and another end connected to the engaging portion.

In an embodiment, the adjustive support portion comprises a rod having an end connected to the coupling portion and another end connected to the engaging portion.

Compared to the prior art, the present invention provides an electronic device supporter installed on a rear-view mirror base inside a vehicle and adapted to hold a vehicle-oriented electronic device. With the electronic device supporter, the vehicle-oriented electronic device is not only firmly installed on the rear-view mirror base, but is also adjustable in terms of position, angle of elevation or angle of depression whichever appropriate.

### BRIEF DESCRIPTION OF THE DRAWINGS

Objectives, features, and advantages of the present invention are hereunder illustrated with specific embodiments in conjunction with the accompanying drawings, in which:

FIG. 1 is a schematic view of an electronic device supporter according to the first embodiment of the present invention;

FIG. 2 is a side view of the electronic device supporter according to the first embodiment of the present invention;

FIG. 3 is a schematic view of the electronic device supporter according to the second embodiment of the present invention; and

FIG. 4 is a schematic view of the electronic device supporter according to the third embodiment of the present invention.

### DETAILED DESCRIPTION

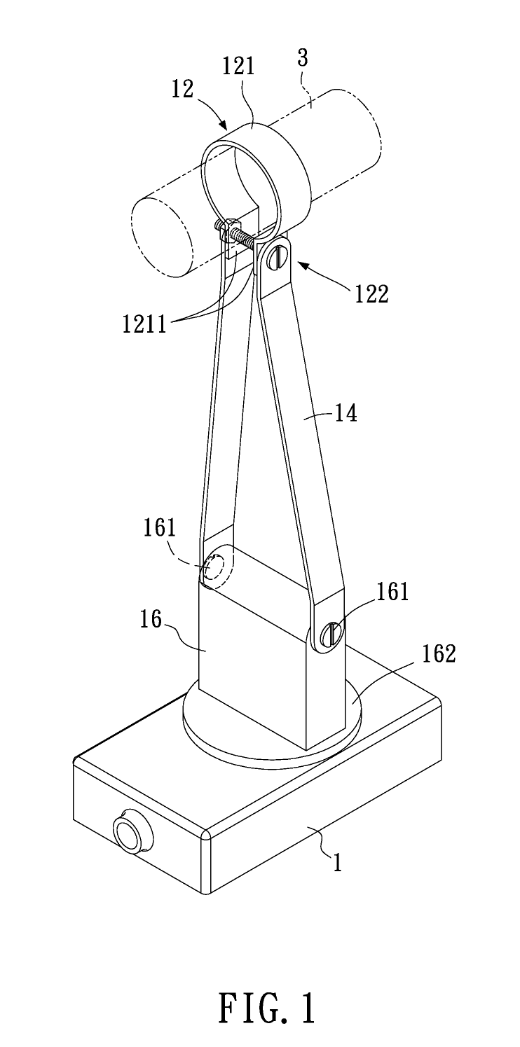

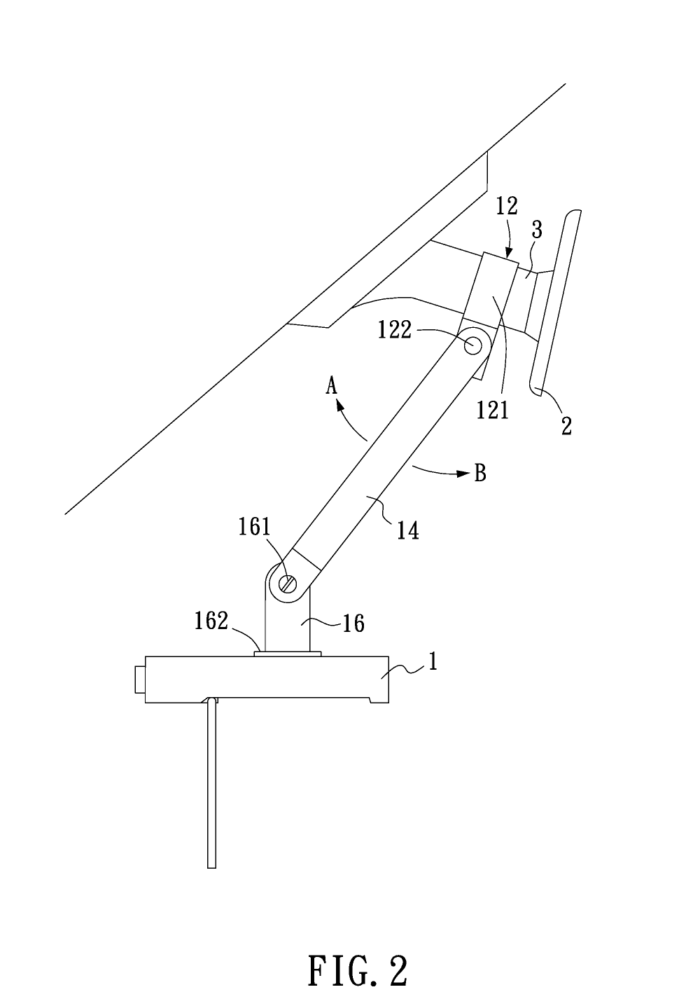

Referring to FIG. 1 and FIG. 2, there are shown a schematic view and a side view of an electronic device supporter according to the first embodiment of the present invention, respectively. As shown in FIG. 1 and FIG. 2, the electronic device supporter fixes an electronic device 1 to a rear-view mirror base 3 inside a vehicle. The rear-view mirror base 3 is coupled to a rear-view mirror 2. The rear-view mirror 2 enables a driver (not shown) to see rearward. The electronic device supporter essentially comprises an engaging portion 12, an adjustive support portion 14, and a coupling portion 16.

The adjustive support portion 14 adjusts the angle of inclination and position of the electronic device 1 relative to the rear-view mirror base 3. The coupling portion 16 is disposed at one end of the adjustive support portion 14 and coupled to the electronic device 1. The engaging portion 12 is disposed at the other end of the adjustive support portion 14. The engaging portion 12 is engaged with and penetrated by the rear-view mirror base 3.

Referring to FIG. 1, in this embodiment, the engaging portion 12 comprises a holding element 121 and an adjusting element 122. The holding element 121 holds the rear-view mirror base 3. The adjusting element 122 not only adjusts the holding element 121 but fastens the holding element 121 to the rear-view mirror base 3, so as to suit the rear-view mirror base 3 of different outer diameter. Hence, the engaging portion 12 not only holds the rear-view mirror base 3, but is fixed to the rear-view mirror base 3.

In this embodiment, the holding element 121 resembles a gapped ring-like structure has two ends separated by the gap. Two plates 1211 corresponding in shape and position to each other extend from the two ends of the holding element 121, respectively. Each of the plates 1211 has a through-hole (not shown). The adjusting element 122 comprises a screw and a screw nut. The adjusting element 122 penetrates the holding element 121. Specifically speaking, the holding element 121 comes in the form of a ring-like structure having a gap separating the two ends of the holding element 121, whereas the adjusting element 122 comprises the screw passing through the through-holes of the plates 1211 separated by a distance, and the screw nut disposed on the outer side of one of the plates 1211. Hence, the holding element 12 can be adjusted with the adjusting element 122 to adjust the distance between the plates 1211, so as to suit the dimensions of an object clamped by the holding element 121. Referring FIG. 1, the process of installation of the electronic device supporter on the rear-view mirror base 3 involves: putting the holding element 121 of the engaging portion 12 around the rear-view mirror base 3; positioning the screw nut of the adjusting element 122 at the through-hole of one of the plates 1211; and passing from the other plate 1211 the screw of the adjusting element 122 through the through-holes of the plates 1211 until the screw reaches the screw nut and meshes therewith. In doing so, the rear-view mirror base 3 can come in different dimensions, such as different outer diameters, and still be efficiently clamped with the holding element 121 by adjusting the depth by which the screw goes beyond the screw nut, or, in other words, the distance between the plates 1211, such that the holding element 121 holds the rear-view mirror base 3 tightly. Conversely, to remove the electronic device supporter from the rear-view mirror base 3, the user loosens the adjusting element 122, that is, the screw nut and the screw, to release the rear-view mirror base 3 from the holding element 121 of the engaging portion 12.

In this embodiment, the adjustive support portion 14 comprises two rods. One end of each of the rods is fastened to the outer side of a corresponding one of the plates 1211 of the engaging portion 12 at the moment when the engaging portion 12 is fixed to the rear-view mirror base 3. The other end of each of the rods is connected to the coupling portion 16. Referring to FIG. 2, the adjustive support portion 14 swings about the adjusting element 122 in direction A or in direction B and thereby adjusts the position of the electronic device 1 relative to the rear-view mirror base 3 as needed. That is to say, the height of the electronic device 1 relative to the user is adjustable. The two rods of the adjustive support portion 14 are capable of absorbing the vibration derived from the vehicle on the move, thereby minimizing the effect of the vehicle-induced vibration upon the stability of the electronic device supporter. The way of installing the two rods of the adjustive support portion 14 is not limited to the disclosure contained in this embodiment and the drawings. The two rods are fastened to one side or two sides of one of the plates 1211 of the holding element 121. Alternatively, the rods are fastened to the inner sides of the plates 1211, respectively. Alternatively, the adjustive support portion 14 is fixed to the engaging portion 12 by means of other fastening elements or screwing elements.

The position of the adjustive support portion 14 on the engaging portion 12 is not limited to the disclosure of this embodiment and the drawings, because it is also feasible to fasten the adjustive support portion 14 to the inner sides of the plates 1211. The shape of the adjustive support portion 14 is not limited to the disclosure of this embodiment and the drawings, but is subject to changes as needed. For example, it is also feasible that the adjustive support portion 14 comprises one and only one rod having one end connected to the coupling portion 16 and the other end having a fastening hole for connection with the engaging portion 12 and still brings about the anticipated advantages of the present invention.

In this embodiment, the coupling portion 16 has one end having a removable connector 162 for connection with the electronic device 1, and has the other end coupled to the adjustive support portion 14 by means of an adjustment element 161. In this embodiment, the adjustment element 161 comprises a screw and a screw nut. Referring to FIG. 2, the adjustive support portion 14 and the coupling portion 16 are rotatable to each other by means of the screwing mechanism of the adjustment element 161; hence, the position of the coupling portion 16 relative to the adjustive support portion 14 is adjustable, so as to adjust the angle of elevation and the angle of depression of the electronic device 1.

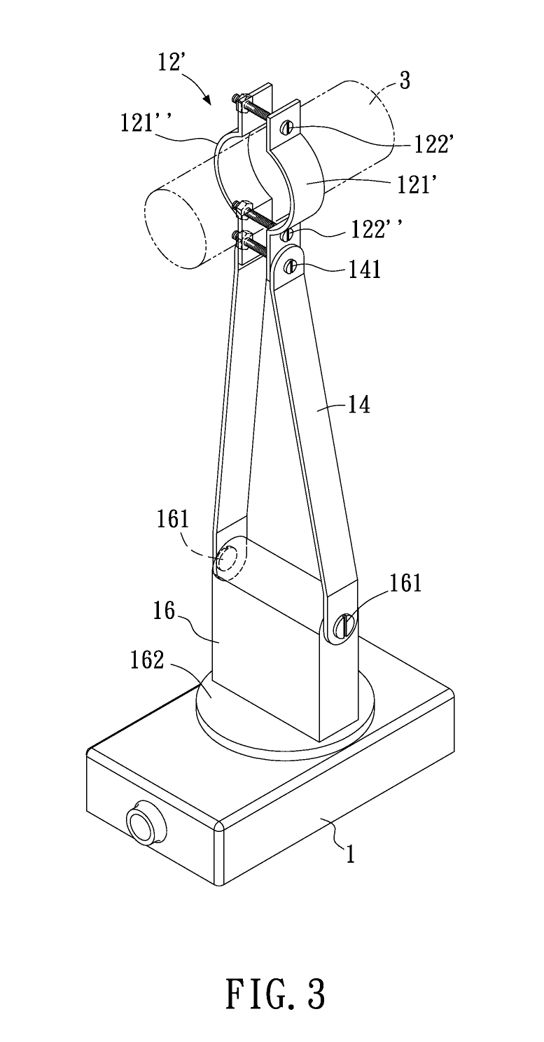

Referring to FIG. 3, there is shown a schematic view of the electronic device supporter according to the second embodiment of the present invention. As shown in FIG. 3, the electronic device supporter comprises an engaging portion 12′, the adjustive support portion 14, and the coupling portion 16. The engaging portion 12′ distinguishes the second embodiment from the first embodiment. The engaging portion 12′ comprises a holding element 121′ and a holding element 121″. The holding element 121′ and the holding element 121″ together form a ring-like structure for holding the rear-view mirror base 3 therein.

In this embodiment, the user installs the electronic device supporter on the rear-view mirror base 3 by following the steps as follows: manipulate the holding element 121′ in a manner that the holding element 121′ approaches and abuts against the rear-view mirror base 3 in a direction perpendicular to the lengthwise direction of the rear-view mirror base 3; and manipulate the holding element 121″ in a manner that the holding element 121″ approaches and abuts against the rear-view mirror base 3 in a direction opposite to that of the holding element 121′. The distance between the holding element 121′ and the holding element 121″ is adjustable by an adjusting element 122′ and an adjusting element 122″. The adjusting element 122′ is disposed at one end of the holding element 121′ and one corresponding end of the holding element 121″, whereas the adjusting element 122″ is disposed at the other end of the holding element 121′ and the other corresponding end of the holding element 121″, so as to couple the holding element 121′ and the holding element 121″ together. The adjusting element 122′ and the adjusting element 122″ each comprises a screw nut and a screw for screwing the holding elements 121′, 121″ tightly enough to fasten the rear-view mirror base 3 therebetween almost in the same way as described in the first embodiment. The two rods of the adjustive support portion 14 are fastened to the outer sides of the holding element 121′ and the holding element 121″ by means of a first fastening element 141, respectively, to effectuate the installation of the adjustive support portion 14. The adjustive support portion 14 can swing about the first fastening element 141. The way of installing the two rods of the adjustive support portion 14 is not limited to the disclosure contained in this embodiment and the drawings. The rods are fastened to the outer side of the holding element 121′ or the outer side of the holding element 121″.

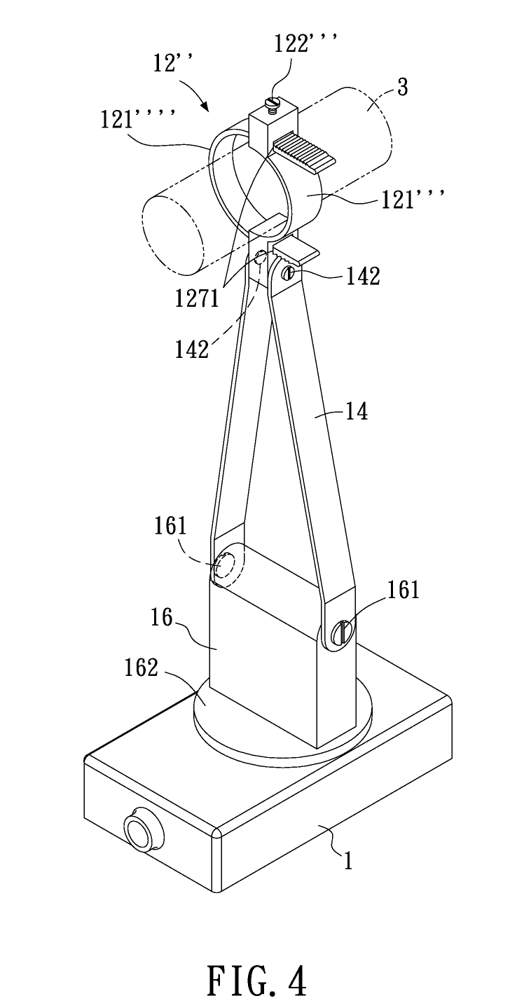

Referring to FIG. 4, there is shown a schematic view of the electronic device supporter according to the third embodiment of the present invention. As shown in FIG. 4, the electronic device supporter comprises an engaging portion 12″, the adjustive support portion 14, and the coupling portion 16. The engaging portion 12″ distinguishes the third embodiment from the first and second embodiments, and comprises a holding element 121″′ and a holding element 121″″. One side of each of the two ends of the holding element 121″″ has a serrate engagement portion. Each of the two ends of the holding element 121″′ has a through hole 1271. The user installs the electronic device supporter on the rear-view mirror base 3 by following the steps as follows: manipulate the holding element 121′ in a manner that the holding element 121″′ approaches and abuts against the rear-view mirror base 3 in a direction perpendicular to the lengthwise direction of the rear-view mirror base 3; manipulate the holding element 121″″ in a manner that the holding element 121″″ approaches and abuts against the rear-view mirror base 3 in a direction opposite to that of the holding element 121′; pass the two ends of the holding element 121″″ through the through holes 1271 of the holding element 121′, respectively; keep adjusting the extent of the holding element 121″″ passing through the through holes 1271 according to the outer diameter of the rear-view mirror base 3 until the holding elements 121′, 121″″ are fastened to the rear-view mirror base 3; press and fasten the holding element 121″″ to the holding element 121″′, such that the engaging portion 12″ holds the rear-view mirror base 3 firmly, by screwing an adjusting element 122″′ penetrating a screw hole (not shown) formed in each of the two ends of the holding element 121″′, wherein the screw hole is in communication with the through hole 1271 formed in each of the two ends of the holding element 121′, and the adjusting element 122″′ is, for example, a screw; and fasten the two rods of the adjustive support portion 14 to the holding element 121″′ with a second fastening element 142.

Furthermore, the electronic device supporter comprises a coupling portion integrally formed with the electronic device and coupled to an adjustive support portion by means of an adjustment element. The adjustment element allows the coupling portion to rotate relative to the adjustive support portion, so as to rotate and adjust the position of the coupling portion relative to the adjustive support portion, thereby adjusting the angle of elevation or angle of depression of the electronic device.

In the aforesaid embodiments, the engaging portion further comprises a resilience element (not shown) which is disposed between a rear-view mirror base and the engaging portion, that is, at the periphery of the rear-view mirror base, so as for the holding elements to clamp and hold the rear-view mirror base better and prevent the engaging portion and the rear-view mirror base from sliding relative to each other and thus losing grip on each other. The resilience element is made of a flexible resilient material, such as rubber or foam.

In conclusion, the present invention provides an electronic device supporter installed on a rear-view mirror base inside a vehicle and adapted to hold a vehicle-oriented electronic device, such as a satellite navigation device, a tachograph, or a cell phone, such that it is convenient for the driver to watch the display of the vehicle-oriented electronic device. With the electronic device supporter, the vehicle-oriented electronic device is not only firmly installed on the rear-view mirror base, but is also adjustable in terms of position, angle of elevation or angle of depression whichever appropriate.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. An electronic device supporter for fixing an electronic device to a rear-view mirror base inside a vehicle, the electronic device supporter comprising:
an adjustive support portion for adjusting a position of the electronic device relative to the rear-view mirror base;
a coupling portion disposed at an end of the adjustive support portion and coupled to the electronic device; and
an engaging portion disposed at another end of the adjustive support portion and engaged with and penetrated by the rear-view mirror base.

2. The electronic device supporter of claim 1, wherein the engaging portion comprises a holding element and an adjusting element, the holding element holding the rear-view mirror base, the adjusting element adjusting and fastening the holding element in place, thereby allowing the engaging portion to be fixed to the rear-view mirror base.

3. The electronic device supporter of claim 2, wherein the holding element is a ring-like structure, and the adjusting element comprises a screw nut and a screw penetrating the holding element and fixed in place by the screw nut.

4. The electronic device supporter of claim 1, wherein the engaging portion further comprises a resilience element disposed between the engaging portion and the rear-view mirror base.

5. The electronic device supporter of claim 2, wherein the engaging portion further comprises a resilience element disposed between the engaging portion and the rear-view mirror base.

6. The electronic device supporter of claim 3, wherein the engaging portion further comprises a resilience element disposed between the engaging portion and the rear-view mirror base.

7. The electronic device supporter of claim 1, wherein the coupling portion comprises an adjustment element for adjusting positions of the adjustive support portion and the coupling portion and fastening the adjustive support portion and the coupling portion in place.

8. The electronic device supporter of claim 1, wherein the coupling portion has a removable connector for connection with the electronic device.

9. The electronic device supporter of claim 1, wherein the coupling portion is integrally formed with the electronic device.

10. The electronic device supporter of claim 1, wherein the adjustive support portion comprises two rods each having an end connected to the coupling portion and another end connected to the engaging portion.

11. The electronic device supporter of claim 1, wherein the adjustive support portion comprises a rod having an end connected to the coupling portion and another end connected to the engaging portion.
